(19) United States
(12) Patent Application Publication
(10) Pub. No.: US 2024/0332913 A1
(43) Pub. Date: Oct. 3, 2024

(54) LIGHT EMITTING DEVICE, RANGING DEVICE, AND MOVABLE OBJECT

(71) Applicant: CANON KABUSHIKI KAISHA, Tokyo (JP)

(72) Inventors: TAKAKO SUGA, Kanagawa (JP); TAKESHI UCHIDA, Kanagawa (JP)

(21) Appl. No.: 18/611,470

(22) Filed: Mar. 20, 2024

(30) Foreign Application Priority Data
Mar. 28, 2023 (JP) 2023-051249

(51) Int. Cl. H01S 5/42; G01S 7/484; G01S 17/10; G01S 17/931; H01S 5/04; H01S 5/06; H01S 5/343

(52) U.S. Cl. CPC H01S 5/426; G01S 7/484; G01S 17/10; G01S 17/931; H01S 5/041; H01S 5/0601; H01S 5/34313; H01S 5/34373

(57) ABSTRACT

A light emitting device includes: a first semiconductor light emitting element that includes a first active layer and a first resonator portion over a semiconductor substrate, and emits a first light; a second semiconductor light emitting element that includes a first reflector, a second resonator portion including a second active layer excited by the first light, and a second reflector stacked in this order over the first semiconductor light emitting element, and emits a second light, wherein an oscillation wavelength of the second semiconductor light emitting element is longer than that of the first semiconductor light emitting element, wherein the second semiconductor light emitting element includes a saturable absorption layer between the second resonator portion and the second reflector, and wherein a thickness L and an absorption coefficient α of the second active layer satisfy the following inequality.

$$\\ 3.45 \leq α \times L \leq 15$$

### BACKGROUND

### Technical Field

The aspect of the embodiments relates to a light emitting device, a ranging device, and a movable object.

### Description of the Related Art

VCSEL (Vertical Cavity Surface Emitting LASER) is known as a light source for a LiDAR (Light Detection and Ranging) of a ToF (Time of Flight) system, which emits light to an object and utilizes a time until the reflected light returns. The VCSEL has a benefit in that the wavelength dependence with respect to temperature is small.

By the way, in the above-described system, it becomes easy to distinguish the ambient light and the light pulse emitted by itself on the light-receiving side by increasing the peak value of the light pulse to be irradiated, whereby the S/N ratio can be increased, and consequently, the maximum measurable distance can be extended. On the other hand, from the viewpoint of eye safety, the peak value of the light pulse is limited. The upper limit of the peak value from the viewpoint of eye safety depends on the width of the light pulse, and the peak value can be increased as the width of the light pulse becomes narrower. Therefore, as a light source applied to the LiDAR system, a light source capable of generating a light pulse having a short light pulse width and a high peak value is used.

As such a light source, International Publication No. WO2022/244674 proposes a high peak value pulse VCSEL having a saturable absorption layer as a VCSEL which realizes a light pulse with a light pulse width narrower than a current pulse width to be injected and a high peak value.

In addition, since the greater the power of the light source is, the longer the measurable distance becomes, in recent years, there has been an increasing need for light sources that generate light pulses in a longer wavelength band of 1,000 nm to 2,000 nm with higher peak values, rather than light pulses in a wavelength band of 800 nm to 900 nm, from the viewpoint of eye safety.

However, there are various issues when fabricating a VCSEL with a wavelength band longer than the wavelength band of 800 nm to 900 nm by current injection. For example, regrowth is used to create a current confinement structure, which is expensive. In addition, a large number of layers of a semiconductor DBR (Distributed Bragg Reflector) are used, and quaternary materials are often needed, resulting in poor heat dissipation and high electrical resistance. Furthermore, the gain of the active layer is low, and it is difficult to significantly increase the number of the active layers.

In order to solve these issues, Japanese Patent Application Laid-Open No. H10-501927 proposes a light emitting device having a configuration in which the output light of a short wavelength VCSEL with a wavelength of 980 nm is used as a pumping light to oscillate a long wavelength VCSEL fabricated on top of the short wavelength VCSEL by photoexcitation.

However, even if the configuration of generating a pulse having a high peak value immediately after the start of laser oscillation described in International Publication No. WO2022/244674 is applied to the optical pumping VCSEL described in Japanese Patent Application Laid-Open No. H10-501927, it is difficult to realize a light pulse having a high peak value in a long wavelength region exceeding a wavelength of 1,000 nm.

### SUMMARY

According to one aspect of the embodiments, there is provided a light emitting device including: a first semiconductor light emitting element that includes a first active layer and a first resonator portion over a semiconductor substrate, and emits a first light; a second semiconductor light emitting element that includes a first reflector, a second resonator portion including a second active layer excited by the first light, and a second reflector stacked in this order over the first semiconductor light emitting element, and emits a second light; and a driving unit that injects a current into the first semiconductor light emitting element, wherein an oscillation wavelength of the second semiconductor light emitting element is longer than an oscillation wavelength of the first semiconductor light emitting element, wherein the second semiconductor light emitting element includes a saturable absorption layer between the second resonator portion and the second reflector, and wherein a thickness L of the second active layer and an absorption coefficient α of the second active layer satisfy the following inequality.

$$\\ 3.45 \leq α \times L \leq 15$$

Further features of the disclosure will become apparent from the following description of exemplary embodiments with reference to the attached drawings.

### BRIEF DESCRIPTION OF THE DRAWINGS

FIG. 1 is a schematic cross-sectional view illustrating a light emitting device according to a first embodiment.

FIG. 2 is a graph illustrating a relationship between the thickness of an active layer and the peak intensity of a light pulse at a start of oscillation in a high peak value type VCSEL.

FIG. 3 is a graph illustrating a relationship between a product α×L and the peak intensity of the light pulse at the start of oscillation in the high peak value type VCSEL.

FIG. 4 is a graph illustrating a relationship between the thickness of the active layer and a wavelength difference with an adjacent longitudinal mode in the high peak value type VCSEL.

FIG. 5 is a schematic cross-sectional view illustrating a high peak value type VCSEL in a light emitting device according to a second embodiment.

FIG. 6 is a graph illustrating a relationship between the amount of light absorbed by an active layer and the position in the thickness direction of the active layer in the high peak value type VCSEL.

FIG. 7 is a schematic cross-sectional view illustrating a high peak value type VCSEL in a light emitting device according to a third embodiment.

FIG. 8 is a schematic cross-sectional view illustrating a light emitting device according to a fourth embodiment.

FIG. 9 is a block diagram illustrating a schematic configuration of a ranging device according to a fifth embodiment.

FIG. 10 is a block diagram illustrating a schematic configuration of a ranging device according to a sixth embodiment.

FIG. 11 is a schematic cross-sectional diagram illustrating an example configuration of a surface light-emitting laser array in the ranging device according to the sixth embodiment.

FIG. 12A and FIG. 12B are diagrams illustrating a configuration example of a movable object according to a seventh embodiment.

FIG. 13 is a schematic cross-sectional view illustrating a light emitting device according to a reference example.

FIG. 14 is a graph illustrating a relationship between the excitation rate of a saturable absorption layer and the shape of a light pulse emitted from a high peak value type VCSEL in the light emitting device according to the reference example.

### DESCRIPTION OF THE EMBODIMENTS

### Reference Example

In a device using the output light of a short wavelength VCSEL described in Japanese Patent Application Laid-Open No. H10-501927 as pumping light, the present inventors have found that a new issue arises when a long wavelength VCSEL excited by the pumping light is simply replaced with a high peak value type VCSEL described in International Publication No. WO2022/244674. Because of this issue, it is difficult to realize a high peak value type VCSEL in a long wavelength region exceeding a wavelength of 1,000 nm even if the configuration of generating a high peak value pulse immediately after a start of laser oscillation described in International Publication No. WO2022/244674 is applied to the VCSEL by optical pumping in Japanese Patent Application Laid-Open No. H10-501927.

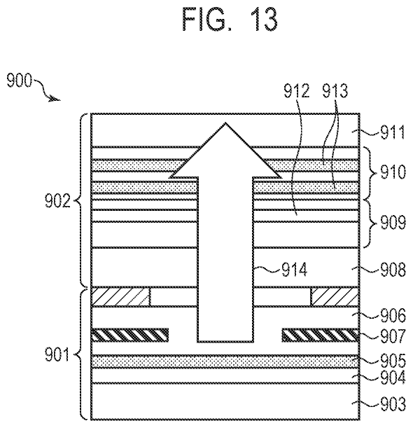

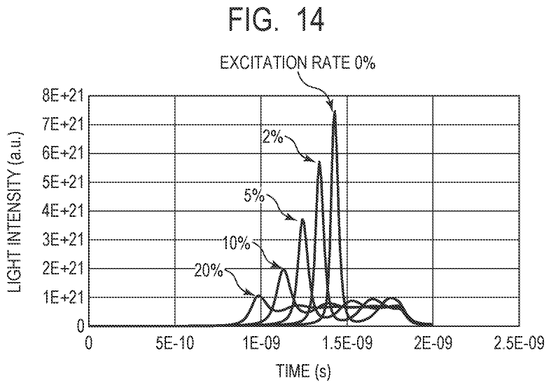

In the present reference example, the new issue that arises when, in the device described in Japanese Patent Application Laid-Open No. H10-501927, the long wavelength VCSEL is simply replaced with the high peak value type VCSEL described in International Publication No. WO2022/244674 will be described with reference to FIG. 13 and FIG. 14.

FIG. 13 is a schematic cross-sectional view illustrating a light emitting device 900 according to the present reference example. The light emitting device 900 according to the present reference example illustrated in FIG. 13 has a structure in which an excitation VCSEL 901 having an oscillation wavelength of 940 nm and a high peak value type VCSEL 902 having an oscillation wavelength of 1550 nm are stacked. The light emitting device 900 includes the excitation VCSEL 901 at a lower part and a high peak value type VCSEL 902 at an upper part.

The excitation VCSEL 901 includes a substrate 903, a lower reflector 904, an active layer 905, an upper reflector 906, and a current confinement portion 907. The lower reflector 904, the active layer 905, and the upper reflector 906 are stacked on the substrate 903 in this order. The current confinement portion 907 is formed in the upper reflector 906. A current is injected into the excitation VCSEL 901 by an upper electrode (not illustrated) on the upper reflector 906 and a lower electrode (not illustrated) under the substrate 903.

The carrier injected from the upper electrode is supplied only to the center of the active layer 905 by the current confinement portion 907 in the upper reflector 906. The excitation VCSEL 901 oscillates by the injection of the current to generate laser light. The laser light is resonated by the upper reflector 906 and the lower reflector 904 to be emitted, and is emitted to the upper part of the excitation VCSEL 901 as the excitation light 914.

The high peak value type VCSEL 902 includes a lower reflector 908, a spacer portion 909, a resonator portion 910, and an upper reflector 911. The lower reflector 908, the spacer portion 909, the resonator portion 910, and the upper reflector 911 are stacked in this order from the side of the excitation VCSEL 901. A saturable absorption layer 912 is arranged in the spacer portion 909. An active layer 913 is arranged in the resonator portion 910.

When the saturable absorption layer 912 is directly excited by excitation light 914 emitted from the excitation VCSEL 901 in the high peak value type VCSEL 902, the pulse intensity of a light pulse emitted from the high peak value type VCSEL 902 is decreased. This decrease in pulse intensity will be further described with reference to FIG. 14.

FIG. 14 is a graph illustrating a relationship between the excitation rate of the saturable absorption layer 912 and the shape of the light pulse emitted from the high peak value type VCSEL 902. In FIG. 14, the horizontal axis indicates time, and the vertical axis indicates the light intensity of light emitted from the high peak value type VCSEL 902.

FIG. 14 reveals that as the excitation rate at which the saturable absorption layer 912 is excited by the excitation light 914 increases, the maximum intensity of the light pulse emitted from the high-peak-value VCSEL 902 decreases. The decrease in the maximum intensity of the light pulse is due to the following reasons. That is, when the excitation light 914 is absorbed by the saturable absorption layer 912, the time for the carriers to increase to the transparent carrier density in the saturable absorption layer 912 becomes shorter than when the excitation light 914 is not absorbed. Accordingly, the time for the carriers to be stored in the active layer 913 is shortened, and as a result, the maximum intensity of the light pulse emitted from the high peak value type VCSEL 902 is decreased.

In contrast, in the following embodiments, a light emitting device including a semiconductor light emitting element that can solve the issue of the configuration illustrated in FIG. 13 above and generate a light pulse with a short light pulse width and a high peak value in the long wavelength region, and the like.

### First Embodiment

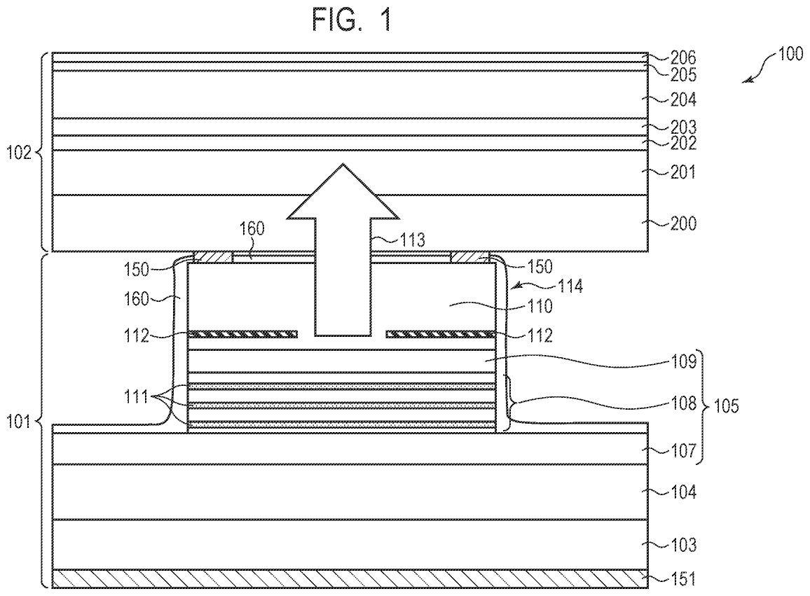

A light emitting device according to a first embodiment of the disclosure will be described with reference to FIG. 1. FIG. 1 is a schematic cross-sectional view illustrating a light emitting device according to the present embodiment.

As illustrated in FIG. 1, the light emitting device 100 according to the present embodiment is a VCSEL that includes an excitation VCSEL 101 having an oscillation wavelength of 940 nm in the lower part and a high peak value type VCSEL 102 having an oscillation wavelength of 1550 nm in the upper part. The light emitting device 100 has a structure in which the high peak value type VCSEL 102 is stacked on the excitation VCSEL 101. The excitation VCSEL 101 is a first semiconductor light emitting element that emits excitation light 113 for exciting the high peak value type VCSEL 102. The high peak value type VCSEL 102 is a second semiconductor light emitting element that is excited by the excitation light 113 to emit a light pulse of a high-peak value.

Note that the oscillation wavelength of the excitation VCSEL 101 and the oscillation wavelength of the high peak value type VCSEL 102 are not limited to the wavelengths described above. The oscillation wavelength of the excitation VCSEL 101 may be, for example, a wavelength in a short wavelength band of 800 nm to 900 nm. The oscillation wavelength of the high peak value type VCSEL 102 may be, for example, a wavelength in a long wavelength band of 1,000 nm to 2,000 nm, and may be longer than the oscillation wavelength of the excitation VCSEL 101.

First, the configuration of the excitation VCSEL 101 will be described. The excitation VCSEL 101 includes a semiconductor substrate 103, a lower DBR layer 104 that is a reflector, a resonator portion 105, an upper DBR layer 110 that is a reflector, electrodes 150 and 151, and a protective film 160. The lower DBR layer 104 is formed on the semiconductor substrate 103. The resonator portion 105 is formed on the lower DBR layer 104. The upper DBR layer 110 is formed on the resonator portion 105.

The resonator portion 105 includes an n-type layer 107 formed on the lower DBR layer 104, an active layer 108 formed on the n-type layer 107, and a p-type layer 109 formed on the active layer 108. The active layer 108 includes a non-doped layer and three layers of quantum wells 111 formed in the non-doped layer. The resonator portion 105 is configured by a p-i-n junction including the n-type layer 107, the active layer 108 including the non-doped layer, and the p-type layer 109. Each of the three layers of the quantum wells 111 included in the active layer 108 can be configured by four InGaAs layers of 8 nm thickness each sandwiched by AlGaAs barrier layers of 10 nm thickness. The n-type layer 107 can be configured by an n-type GaAs layer, the p-type layer 109 can be configured by a p-type GaAs layer, and the non-doped layer of the active layer 108 can be configured by a non-doped GaAs layer. An oxidized confinement layer 112 is formed in the upper DBR layer 110.

The active layer 108, the p-type layer 109 and the upper DBR layer 110 on the upper side of the n-type layer 107 are processed into a mesa shape to constitute a mesa portion 114. The electrode 150 electrically connected to the upper DBR layer 110 is formed on the upper DBR layer 110. The electrode 151 electrically connected to the semiconductor substrate 103 by an ohmic contact is formed on the back surface of the semiconductor substrate 103. A driving unit that injects drive current for driving the excitation VCSEL 101 into the excitation VCSEL 101 is electrically connected to the electrodes 150 and 151.

The protective film 160 is formed on the upper surface of the n-type layer 107 exposed by processing the active layer 108, the p-type layer 109 and the upper DBR layer 110 into the mesa shape, on the upper surface of the mesa portion 114 excluding at least a part of the surface of the electrode 150, and on the side surfaces of the mesa portion 114. The protective film 160 is formed for preventing deterioration of the semiconductor surface.

The semiconductor substrate 103 may be formed of, for example, an n-type GaAs substrate. The lower DBR layer 104 may be, for example, configured by stacking thirty-five pairs with a stacked body of an Al_{0.1}GaAs layer and an Al_{0.9}GaAs layer having an optical thickness of ¼λc as one pair. Here, λc is the center wavelength of the high reflection band of the lower DBR layer 104, which is 940 nm in the present embodiment.

The upper DBR layer 110 may be, for example, configured by stacking twenty pairs with a stacked body of an Al_{0.1}GaAs layer and an Al_{0.9}GaAs layer having an optical thickness of ¼λc as one pair. The oxidized confinement layer 112 formed by oxidizing a part of an Al_{0.98}GaAs layer having a thickness of 30 nm is formed in the upper DBR layer 110. The oxidized confinement layer 112 may be formed, for example, by oxidizing the Al_{0.98}GaAs layer laterally from the side surface of the mesa portion 114 with water vapor at the time of manufacture. The oxidized confinement layer 112 includes a non-oxidized portion at the center of the mesa portion 114 and an oxidized portion of a predetermined length near the sidewall of the mesa portion 114. Thus, since the current injected into the excitation VCSEL 101 flows only in the non-oxidized portion, only the portion overlapping the central portion of the mesa portion 114 in the plan view of the excitation VCSEL 101 performs laser oscillation.

The laser light generated in the excitation VCSEL 101 is emitted from the side of the upper DBR layer 110 and enters the high peak value type VCSEL 102 stacked on the excitation VCSEL 101 as the excitation light 113. The mesa portion 114 in the excitation VCSEL 101 functions as a light emitting portion that emits the excitation light 113.

Next, the configuration of the high peak value type VCSEL 102, which is photoexcited by the excitation light 113, will be described. The high peak value type VCSEL 102 includes a lower DBR layer 200 that is a reflector, an active layer 201, a carrier blocking layer 202, a saturable absorption layer 203, an upper DBR layer 204 that is a reflector, a semiconductor substrate 205, and an AR coating 206. The lower DBR layer 200 is arranged on the mesa portion 114 including the active layer 108, the p-type layer 109, and the upper DBR layer 110 of the excitation VCSEL 101. The active layer 201 is formed on the lower DBR layer 200. The carrier blocking layer 202 is formed on the active layer 201. The saturable absorption layer 203 is formed on the carrier blocking layer 202. The upper DBR layer 204 is formed on the saturable absorption layer 203. The semiconductor substrate 205 is formed on the upper DBR layer 204. The AR coating 206 is formed on the semiconductor substrate 205. The excitation light 113 enters the high peak value type VCSEL 102 from the side of the lower DBR layer 200.

The lower DBR layer 200 may be, for example, configured by stacking seven pairs with a stacked body of SiO₂ layer and TiO₂ layer, which is a SiO₂/TiO₂ layer and has an optical thickness of ¼λd, as one pair. Here, λd is the center wavelength of the high reflection band of the lower DBR layer 200, which is 1550 nm in the present embodiment.

A resonator portion is a layer between the lower DBR layer 200 and the upper DBR layer 204. The active layer 201 constitutes the resonator portion. The active layer 201 may also constitute the resonator portion together with other semiconductor layers stacked above and below the active layer. In the present embodiment, the resonator portion is configured by the active layer 201, the carrier blocking layer 202, and the saturable absorption layer 203. In the disclosure, the active layer refers to a region in the resonator where an inversion distribution is caused by excitation light. In the present embodiment, the active layer 201 is a layer formed of a layer having a band gap smaller than the photon energy of the excitation light 113, and is located on the incident side of the excitation light 113 than the saturable absorption layer 203 in the resonator. The saturable absorption layer 203 is located farther from the incident side of the excitation light 113 than the active layer 201. The active layer 201 may include, for example, a plurality of quantum well layers formed of InGaAs and a plurality of barrier layers formed of InGaAsP formed above and below each quantum well layer. Specifically, the active layer 201 may have, for example, a quantum well structure in which five InGaAs quantum well layers of 8 nm thickness and a plurality of InGaAsP barrier layers formed above and below each quantum well layer, to have 3.2 μm thickness. Note that the thickness of the active layer 201 is not limited thereto, and may be determined as described later. In this case, the positions of the InGaAs quantum well layers are the antinode positions of a standing wave generated in the active layer 201. Specifically, the positions of the five InGaAs quantum well layers in the thickness direction of the active layer 201 are as follows, when the end of the active layer 201 at which the excitation light 113 enters is set to 0 nm. That is, the first layer is located at around 686 nm, the second layer is located at around 1143 nm, the third layer is located at around 1600 nm, the fourth layer is located at around 2057 nm, and the fifth layer is located at around 2971 nm. The center of gravity of these five InGaAs quantum well layers is centered in the thickness direction of the active layer 201. Thus, the plurality of quantum well layers in the active layer 201 are positioned in the antinode positions of the standing wave generated in the active layer 201, and the center of gravity of the plurality of quantum well layers is centered in the thickness direction of the active layer 201. In the present embodiment, as an example of the active layer 201, a layer formed of a layer having a band gap smaller than the photon energy of the excitation light 113 is used, but the disclosure is not limited thereto, and a part of the active layer 201 may include a layer having a band gap larger than the photon energy of the excitation light 113. In this case, the thickness of the active layer 201 is the total thickness of only the layer having a band gap smaller than the photon energy of the excitation light 113.

The thickness of the active layer 201, which may be configured as described above, is 3.2 μm, which is thicker than the thickness in a typical VCSEL configuration. Such a relatively thick active layer 201 is configured to solve the issue that is caused by using the high peak value type VCSEL 102 as the photoexcited type VCSEL. This point will be explained in detail below.

On the active layer 201, the carrier blocking layer 202 having an optical thickness of ½λd and the saturable absorption layer 203 are stacked in this order. The carrier blocking layer 202 has a function to prevent carriers generated in the active layer 201 by photoexcitation by the excitation light 113 from flowing into the saturable absorption layer 203. The saturable absorption layer 203 is arranged on the opposite side to the excitation VCSEL 101 across the active layer 201. That is, the saturable absorption layer 203 is formed between the active layer 201 and the upper DBR layer 204.

The carrier blocking layer 202 is formed between the active layer 201 and the saturable absorption layer 203. The carrier blocking layer 202 may be formed of, for example, an InP layer.

The saturable absorption layer 203 may include, for example, a plurality of quantum well layers formed of InGaAs and a plurality of barrier layers formed of InGaAsP formed above and below each quantum well layer. Specifically, the saturable absorption layer 203 may have four InGaAs quantum well layers of 8 nm thickness and InGaAsP barrier layers arranged above and below each quantum well layer.

The upper DBR layer 204 arranged on the saturable absorption layer 203 may be, for example, an InP/InGaAsP layer and may be configured by stacking a plurality of pairs with a stacked body of an InP layer and an InGaAsP layer having an optical thickness of ¼λd as one pair.

The semiconductor substrate 205 arranged on the upper DBR layer 204 may be, formed of, for example, an InP substrate. The AR (Anti-Reflection) coating 206 is formed on the surface of the semiconductor substrate 205 to reduce light reflection at the interface between the semiconductor substrate 205 and air.

As described in the above reference example, when the saturable absorption layer is directly excited even at a few percent of the total energy of the excitation light, the pulse intensity of the short pulse at the start of oscillation obtained by the high peak value type VCSEL decreases. Therefore, in the present embodiment, the thickness of the active layer 201 is set so that the excitation light 113 is sufficiently absorbed by the active layer 201. Specifically, in one embodiment, the thickness of the active layer 201 is set such that the amount of absorption of the excitation light 113 by the active layer 201 is preferably 90% or more, more preferably 95% or more.

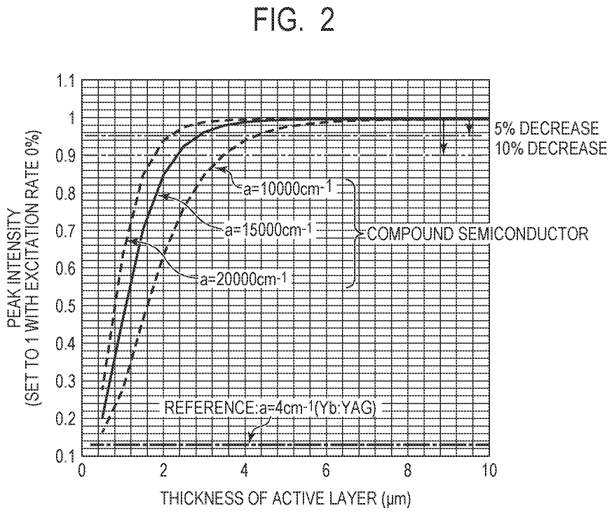

FIG. 2 is a graph illustrating calculation results of the relationship between the thickness of the active layer 201 in the high peak value type VCSEL 102 and the pulse intensity (peak intensity) of the light pulse which is a short pulse at the start of oscillation emitted from the high peak value type VCSEL 102. Here, the configuration including the material of the excitation VCSEL 101 and the high peak value type VCSEL 102 is as illustrated above. In FIG. 2, the horizontal axis indicates the thickness of the active layer 201, and the vertical axis indicates the peak intensity of the light pulse. The peak intensity of the light pulse is set to 1 when the thickness of the active layer 201 is sufficiently thick and there is no influence of the excitation light 113 on the saturable absorption layer 203, that is, when the excitation rate of the saturable absorption layer 203 is 0%, and is expressed as a ratio with respect to this. Note that FIG. 2 illustrates a solid line for a case where the absorption coefficient α described below is 15,000 cm⁻¹, and broken lines for a case where the absorption coefficient α is 10,000 cm⁻¹ and a case where the absorption coefficient α is 20,000 cm⁻¹, respectively. Also note that, for reference, a dot and dash line for a case of Yb:YAG (Ytterbium doped Yttrium Aluminum Garnet) crystal where the absorption coefficient α is 4 cm⁻¹ is indicated.

In the materials used in the present embodiment, the absorption coefficient α of the active layer 201 for the excitation light 113 is 15,000 cm⁻¹. In this case, as indicated by the solid line in FIG. 2, the peak intensity decreases by 5% when the thickness of the active layer 201 decreases to 2.8 μm, the peak intensity decreases by 10% when the thickness decreases to 2.3 μm, and the peak intensity decreases rapidly when this thickness becomes thinner. Therefore, in this case, the thickness of the active layer 201 is preferably 2.3 μm or more and more preferably 2.8 μm or more from the viewpoint of suppressing the decrease in the peak intensity of the light pulse to a small degree.

When light passes through a material having an absorption coefficient α and a length L, the light transmittance I is expressed by the following expression.

$$\\ I = exp ( - α \times L )$$

Therefore, even when the absorption coefficient α of the active layer is changed, if the product of the absorption coefficient α of the active layer and the length (thickness) L of the active layer is constant, the amount of light transmitted becomes the same value. Therefore, the product α×L of the absorption coefficient α of the active layer and the thickness L of the active layer can provide a guideline for a preferable value of the thickness of the active layer.

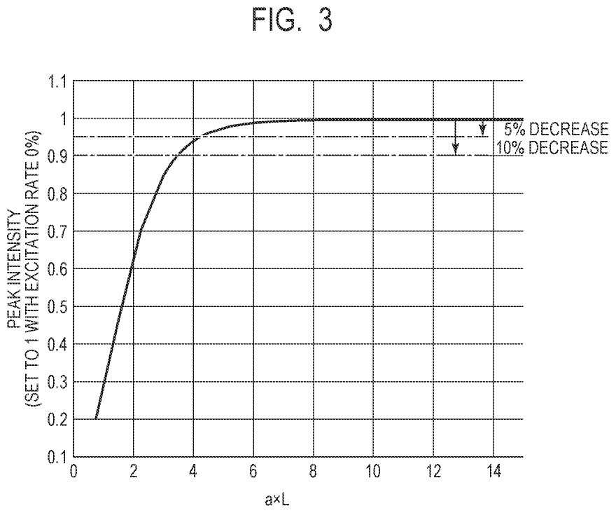

FIG. 3 is a graph illustrating the peak intensity of the light pulse on the vertical axis as in FIG. 2, where the absorption coefficient α illustrated in FIG. 2 is 15,000 cm⁻¹, with the horizontal axis as the product α×L of the absorption coefficient α of the active layer 201 and the thickness L of the active layer 201. When the thickness of the active layer 201 is expressed by the product α×L, the thickness of 2.3 μm corresponds to 3.45 in the product α×L, and the thickness of 2.8 μm corresponds to 4.2 in the product α×L.

In general, the absorption coefficient α of the active layer 201 for light having a wavelength larger than the band gap is often 10,000 cm⁻¹ to 20,000 cm⁻¹ depending on the material composition or the like. In FIG. 2, the calculated results of the relationship between the thickness of the active layer 201 and the peak intensity of the light pulse are indicated by broken lines for the cases where the absorption coefficients α of the active layer 201 for the excitation light 113 are 10,000 cm⁻¹ and 20,000 cm⁻¹, respectively. Considering such absorption coefficients α, in one embodiment, it can be also said that the thickness of the active layer 201 is preferably 1.8 μm or more, or more preferably 2.4 μm or more, or preferably 3.5 μm or more, according to FIG. 2, from the same viewpoint as described above. Note that these 1.8 μm, 2.4 μm, and 3.5 μm are the thicknesses of the active layer when the peak intensity decreases by 10% when the absorption coefficient α is 20,000 cm⁻¹, 15,000 cm⁻¹, and 10,000 cm⁻¹, respectively.

On the other hand, one of the disadvantages of the increase in the thickness of the active layer and the increase in the length of the resonator is that the spacing between adjacent longitudinal modes becomes shorter. More specifically, when the spacing between adjacent longitudinal modes is shortened, the difference between the gain wavelength in the active layer and the difference in the reflectance in the reflector becomes smaller between the longitudinal modes, and a so-called mode hop in which the oscillation moves to another longitudinal mode is likely to occur. The occurrence of the mode hop means that the oscillation wavelength of the laser changes. In the case of VCSEL, the wavelength difference from the adjacent longitudinal mode, which is the wavelength at which the oscillation wavelength changes, generally exceeds 10 nm. When a light emitting device is used for ranging applications, since a bandpass filter having a transmission wavelength band of several nm is usually arranged on the light receiving side, the phenomenon of the mode hop is preferably avoided. In general, in one embodiment, in order to avoid the phenomenon of the mode hop, it is preferable to secure a wavelength difference of 30 nm or more from the adjacent longitudinal mode, and preferably to secure 50 nm or more. This is because the wavelength difference from the adjacent longitudinal mode can provide a sufficient difference in the gain obtained in the active layer between the adjacent longitudinal modes, and as a result, the mode hop can be suppressed. In this embodiment, all of the barrier layers are InGaAsP, but the disclosure is not limited thereto. The barrier layer may have a band gap larger than that of the quantum well layer and a band gap smaller than that of the excitation light. Further, not all barrier layers may have the same band gap and may have a plurality of band gaps.

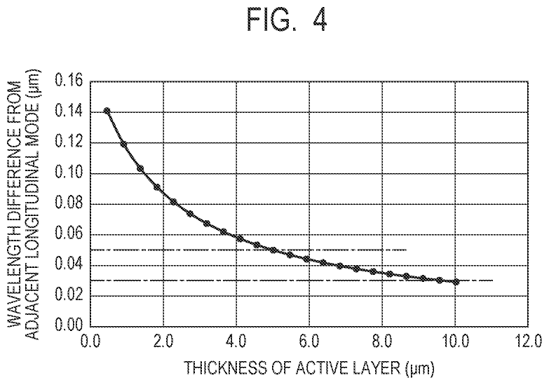

FIG. 4 is a graph illustrating a relationship between the thickness of the active layer 201 and the wavelength difference from the adjacent longitudinal mode in the high peak value type VCSEL 102. Here, the configuration including the materials of the excitation VCSEL 101 and the high peak value type VCSEL 102 is as illustrated above. As illustrated in FIG. 4, the wavelength difference from the adjacent longitudinal mode is 50 nm when the thickness of the active layer 201 is 5 μm, and the wavelength difference from the adjacent longitudinal mode is 30 nm when the thickness of the active layer 201 is 10 μm. Therefore, in one embodiment, the upper limit value of the thickness of the active layer 201 is preferably 10 μm, and more preferably 5 μm. When the thickness of the active layer 201 is expressed by the product α×L of the absorption coefficient α and the length L of the active layer 201, the thickness of 10 μm corresponds to 15 in the product α×L, and the thickness of 5 μm corresponds to 7.5 in the product α×L.

In the high peak value type VCSEL 102 configured in this way, the active layer 201 is photoexcited by the excitation light 113 from the lower excitation VCSEL 101 to generate a light pulse of a high peak value and a short pulse as the light to be emitted. The light pulse is emitted from the side of the semiconductor substrate 205 outside the high peak value type VCSEL 102.

The high peak value type VCSEL 102 is capable of emitting light having a maximum peak value and a profile converging after the maximum peak value to a stable value which is a prescribed light intensity. That is, in the high peak value type VCSEL 102, laser oscillation is inhibited by the saturable absorption layer 203 for a certain time from the incidence of the excitation light 113, and carriers exceeding a threshold carrier density are accumulated in the active layer 201. Here, the threshold carrier density is a carrier density that generates a gain necessary for performing laser oscillation. Thereafter, when the laser oscillation starts in the high peak value type VCSEL 102, the carriers are rapidly consumed by stimulated emission and converges to a stable value. Thus, in the high peak value type VCSEL 102, more carriers are accumulated in the active layer 201 beyond the threshold carrier density. After the start of the laser oscillation, the carriers accumulated in the active layer 201 are converted into photons by stimulated emission. Thus, the high peak value type VCSEL 102 can output the light pulse of the high peak value and the short pulse.

As described above, in the light emitting device 100 according to the present embodiment, the following three elements are added to the high peak value type VCSEL 102. The first of the three elements added to the high peak value type VCSEL 102 is that the saturable absorption layer 203 is arranged on the opposite side to the excitation VCSEL 101 across the active layer 201. That is, the saturable absorption layer 203 is arranged between the resonator portion configured by the active layer 201 and the upper DBR layer 204. The second is that the thickness of the active layer 201 is such that the amount of absorption of the excitation light 113 by the active layer 201 is, in one embodiment, preferably 90% or more, more preferably 95% or more. The third is that the carrier blocking layer 202 is arranged between the resonator portion and the saturable absorption layer 203, that is, between the active layer 201 and the saturable absorption layer 203. By adding at least the first and second of these three elements, and in one embodiment, further adding the third of these three elements, the amount of absorption by which the excitation light 113 is absorbed by the saturable absorption layer 203 can be decreased to a small extent. In the present embodiment, in the case of the above-described exemplary material composition, the amount of absorption of the excitation light 113 incident on the high peak value type VCSEL 102 that is absorbed by the saturable absorption layer 203 is decreased to 0.4%.

Note that, with respect to the second of the three elements, the thickness of the active layer 201 can be defined as follows from the viewpoint of suppressing the decrease in the peak intensity of the light pulse to a small degree and avoiding the mode hop as described above.

First, the thickness L of the active layer 201 can be defined by the product α×L of the absorption coefficient α of the active layer 201 and the thickness L of the active layer 201. Specifically, in one embodiment, the product α×L preferably satisfies the following expression (1), and more preferably satisfies the following expression (2).

$$\\ \begin{matrix}3.45 \leq α \times L \leq 15 & ( 1 )\end{matrix}$$

$$\\ \begin{matrix}4.2 \leq α \times L \leq 7.5 & ( 2 )\end{matrix}$$

Further, in another embodiment, the thickness L of the active layer 201 preferably satisfies the following expression (3), and more preferably satisfies the following expression (4).

$$\\ \begin{matrix}2.3 µm \leq L \leq 10 µm & ( 3 )\end{matrix}$$

$$\\ \begin{matrix}2.8 µm \leq L \leq 5 µm & ( 4 )\end{matrix}$$

Thus, according to the present embodiment, the decrease of peak intensity in the light pulse having a high peak value and a short pulse emitted from the high peak value type VCSEL 102 can be suppressed to a small extent. Therefore, according to the present embodiment, it is possible to realize a light emitting device 100 capable of generating a light pulse having a short light pulse width and a high peak value in a long wavelength region. Thus, by configuring the high peak value type VCSEL 102 itself to generate a light pulse having a short pulse, it is possible to realize a light pulse having a short pulse width, which is preferable for the LiDAR system, while avoiding the cost increase of the driver unit and the electric transmission unit. Specifically, it is possible to realize a light pulse having a short pulse width, which is preferable for the LiDAR system, of about 50 ps to 1 ns. Furthermore, since a light pulse can be generated in a long wavelength region, the upper limit value of the peak value of the light pulse from the viewpoint of eye safety can be increased.

Next, an example of the manufacturing method of the light emitting device 100 according to the present embodiment will be described below.

First, the semiconductor layers constituting the excitation VCSEL 101 and the semiconductor layers constituting the high peak value type VCSEL 102 are separately grown on the semiconductor substrate 103 and the semiconductor substrate 205, respectively, by metalorganic vapor deposition or molecular beam epitaxy. Thus, the growth wafers for the excitation VCSEL 101 and the high peak value type VCSEL 102 are prepared, respectively. As the semiconductor layers constituting the excitation VCSEL 101, the semiconductor layers constituting the lower DBR layer 104, the resonator portion 105 and the upper DBR layer 110 are grown on the semiconductor substrate 103. As the semiconductor layers constituting the high peak value type VCSEL 102, the semiconductor layers constituting the upper DBR layer 204, the saturable absorption layer 203, the carrier blocking layer 202, the active layer 201 and the lower DBR layer 200 are grown on the semiconductor substrate 205.

Further, the following steps are performed for the growth wafer for the excitation VCSEL 101.

First, the upper DBR layer 110, the p-type layer 109 and the active layer 108 are patterned using etching techniques such as photolithography and dry etching, or the like. Thus, the columnar mesa portion 114 having a diameter of about 30 μm is formed. Note that, in the patterning, the resonator portion 105 around the mesa portion 114 or below may be removed by the etching.

Then, thermal oxidation is performed in a steam atmosphere of about 450° C., and the Al_{0.98}Ga_{0.02}As layer in the upper DBR layer 110 is oxidized from the sidewall portion of the mesa portion 114 to form the oxidized confinement layer 112. At this time, by controlling the oxidation time, the non-oxidation portion of the central body of the mesa portion 114 and the oxidation portion (the oxidized confinement layer 112) near the sidewall of the mesa portion 114 are formed. For the non-oxidation portion of the Al_{0.98}Ga_{0.02}As layer, the oxidation time is controlled so that the diameter of the non-oxidation portion is about 10 μm.

The protective film 160, which is an insulating film, is formed so as to cover the mesa side surface and the etched portion by using plasma CVD method, which is a deposition method of an insulating film, and a lithography method, which is a pattern formation method. Then, an opening is formed in a part on the protective film 160 on the upper surface of the mesa portion 114 and the electrode 150 serving as a p-side electrode is formed in the part by using photolithography and vacuum deposition. The electrode 151 serving as an n-side electrode is formed on the surface of the semiconductor substrate 103 opposite to the mesa portion 114. The electrode 150 has an annular pattern, and the central opening serves as a circular window for light extraction. Note that, in the present embodiment, the electrode 150 has an annular pattern, but the disclosure is not limited thereto, and the electrode 150 may be, for example, square, rectangular, or other polygonal shape.

Then, in order to obtain good electrical characteristics, heat treatment is performed in a high temperature nitrogen atmosphere, and the interface between the electrode material and the semiconductor material is alloyed to complete the excitation VCSEL 101. If necessary, by forming a plurality of mesa portions 114 in the excitation VCSEL 101 it is possible to simultaneously form a plurality of light emitting portions in the plane of the high peak value type VCSEL 102 corresponding to the plurality of mesa portions 114. A configuration in which the plurality of light emitting portions are formed will be described in the fourth embodiment.

Next, the growth wafer for the high peak value type VCSEL 102 is stacked on the excitation VCSEL 101 formed as described above, with the lower DBR layer 200 on the side of the excitation VCSEL 101 and the semiconductor substrate 205 on the upper side. The stacking method is not particularly limited, and can be appropriately selected. For example, the growth wafer for the high peak value type VCSEL 102 can be stacked on a surface other than a portion where the excitation light 113 of the excitation VCSEL 101 is emitted by using an adhesive having a low absorption rate of the excitation light 113. Also, for example, gold can be deposited on a surface other than a portion of the lower DBR layer 104 where the excitation light 113 is incident on the growth wafer for the high peak value type VCSEL 102, and the gold can be bonded to gold deposited on the upper surface of the excitation VCSEL 101 to make the excitation VCSEL 101 and the high peak value type VCSEL 102 stacked.

Next, the semiconductor substrate 205 is thinned before or after the stacking as required. Finally, the AR coating 206 is deposited on the surface of the semiconductor substrate 205 in the high peak value type VCSEL 102. Thus, the light emitting device 100 according to the present embodiment is manufactured.

Thus, according to the present embodiment, it is possible to realize the light emitting device 100 capable of generating a light pulse having a short light pulse width and a high peak value in a long wavelength region.

### Second Embodiment

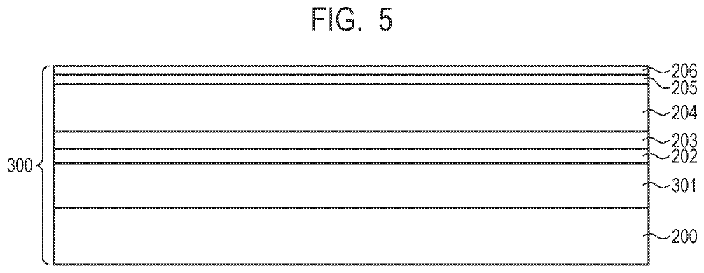

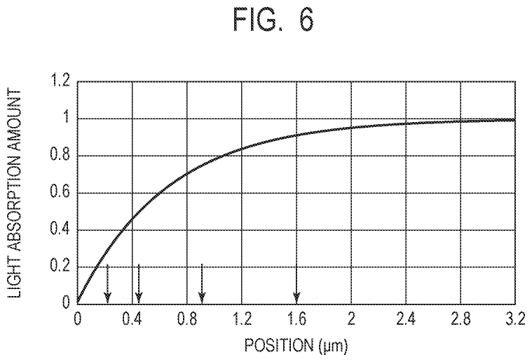

A light emitting device according to a second embodiment of the disclosure will be described with reference to FIG. 5 and FIG. 6. Components similar to those of the light emitting device according to the first embodiment are denoted by the same reference numerals, and description thereof will be omitted or simplified.

The light emitting device according to the present embodiment is similar to the light emitting device according to the first embodiment except that the configuration of the high peak value type VCSEL is different from that of the light emitting device according to the first embodiment, and has an excitation VCSEL similar to that of the first embodiment. In the present embodiment, parts different from the light emitting device according to the first embodiment will be described mainly, and parts common to the light emitting device according to the first embodiment will be omitted appropriately.

FIG. 5 is a schematic cross-sectional view illustrating a high peak value type VCSEL 300 in the light emitting device according to the present embodiment. The light emitting device according to the present embodiment includes the high peak value type VCSEL 300 instead of the high peak value type VCSEL 102 in the configuration according to the first embodiment. The configuration of the light emitting device according to the present embodiment other than the high peak value type VCSEL 300 is the same as that according to the first embodiment.

The high peak value type VCSEL 300 differs from the high peak value type VCSEL 102 in that the active layer 201 is replaced by the active layer 301 in which the positions of the quantum well layers are optimized according to the absorption characteristics of the excitation light 113. The active layer 301, like the active layer 201, may have a quantum well structure in which five InGaAs quantum well layers of 8 nm thickness are arranged in the InGaAsP barrier layer, to have 3.2 μm thickness. One the other hand, the active layer 301 differs from the active layer 201 in that the positions of the quantum well layers are optimized in accordance with the absorption characteristics of the excitation light 113, as described below. Note that the configuration other than the active layer 301 of the high peak value type VCSEL 300 is the same as that of the high peak value type VCSEL 102.

FIG. 6 is a graph illustrating the light absorption amount which is the ratio of the excitation light 113 absorbed by the active layer 301 when the excitation light 113 advances in the active layer 301 from the end to a specific distance in the thickness direction of the active layer 301. In FIG. 6, the horizontal axis indicates the position of the active layer 301 in the thickness direction with the boundary between the active layer 301 and the lower DBR layer 200 as the position of 0 μm which is the end on which the excitation light 113 enters. The vertical axis indicates the integrated value of the light absorption amount from 0 μm to the position of the horizontal axis.

FIG. 6 shows that the slope of the graph is large near the position of 0 μm, that is, the light absorption amount per unit length in the thickness direction of the active layer 301 is large. This means that the carrier generation amount in the active layer 301 is large near the position of 0 μm.

Therefore, in the present embodiment, the plurality of quantum well layers are arranged in the active layer 301 at an optimum position, specifically, they are arranged more on the side near the end where the excitation light 113 enters, taking into account the deviation of the amount of generation of carriers in the active layer 301. In the present embodiment, the plurality of quantum well layers in the active layer 301 are arranged at positions indicated by arrows in FIG. 6, and are arranged biased in the thickness direction of the active layer 301 to the side of the end where the excitation light 113 enters the active layer 301.

More specifically, the positions of the quantum well layers in the active layer 301 according to the present embodiment can be set as follows.

When there are five quantum well layers, for the amount of light absorption illustrated in FIG. 6, in one embodiment, the quantum well layers is placed at positions with light absorption of 0.1, 0.3, 0.5, 0.7, and 0.9, respectively, in terms of the carrier absorption. On the other hand, a higher amplification gain of light can be obtained by placing the quantum well layers at the antinode positions of the standing wave generated in the active layer 301.

Considering the two viewpoints of the carrier absorption and the amplification gain of the light, it is possible to place the five quantum well layers at the skipping positions, which are the antinodes of the standing wave, and close to the positions where the light absorption amounts are 0.1, 0.3, 0.5, 0.7, and 0.9. The specific positions of the quantum well layers in the active layer 301 thus set in the present embodiment are indicated by the arrows in FIG. 6. As illustrated in FIG. 6, the quantum well layers of five layers are arranged at intervals of an integral multiple of about 229 nm in the thickness direction of the active layer 301 as the antinode positions of the standing wave in the active layer 301. First, two quantum well layers are arranged at positions near 229 nm, then one quantum well layer is arranged at a position near 457 nm, then one quantum well layer is arranged at a position near 914 nm, and finally one quantum well layer is arranged at a position near 1.6 μm. On the other hand, no quantum well layer is arranged between a position of 1.6 μm and a position of 3.2 μm in the active layer 301. The center of gravity of the quantum well layer of five layers arranged in this manner is located at a position of near 686 nm, and is located on the side of the end of the active layer 301 on which the excitation light 113 enters rather than the center of the active layer 301 in the thickness direction.

Thus, in the present embodiment, in the active layer 301, the plurality of quantum well layers are arranged in a biased manner at the end of the active layer 301 on which the excitation light 113 enters. That is, the center of gravity of the plurality of quantum well layers in the active layer 301 is located at the end of the active layer 301 on which the excitation light 113 enters rather than at the center of the active layer 301 in the thickness direction. Thus, the carriers generated in the active layer 301 can be injected into the plurality of quantum well layers more uniformly than in the first embodiment. As a result, according to the present embodiment, the peak power of the high peak value light pulse emitted from the high peak value type VCSEL 300 can be increased more than in the first embodiment, and a light source device having excellent power conversion efficiency can be realized.

Here, as can be seen from FIG. 6, no quantum well layer is arranged in the present embodiment between the position of 1.6 μm and the position of 3.2 μm because there is little generation of carriers. When the thickness of the active layer 301 is 1.6 μm, 90% of the excitation light 113 is absorbed. On the other hand, even if the thickness of the active layer 301 is increased to be doubled to 3.2 μm, light energy absorbed by the increased amount is less than 10%. Therefore, in terms of the amount of excitation light 113 absorbed by the active layer 301, the effect of increasing the thickness of the active layer 301 to the double of 1.6 μm, that is, 3.2 μm, is small.

In the design concept of an ordinary photoexcited VCSEL that is not a high peak value type, only the amount of excitation light absorbed by the active layer 301 is considered. Therefore, according to this design concept, the absorption rate of the excitation light by the active layer when the excitation light propagates from the end to the end of the active layer is often kept at 90% or less when the balance with the thickness of the active layer is taken into consideration, that is, the thickness of the active layer is often kept at 1.6 μm or less.

On the other hand, in the high peak value type VCSELs 102 and 300, which are photoexcited type and high peak value type VCSELs, it is important not to excite the saturable absorption layer 203 located at the end where the excitation light 113 has passed through the active layers 201 and 301. Therefore, in the high peak value type VCSELs 102 and 300, a unique design concept of absorbing the excitation light 113 and preventing it from reaching the saturable absorption layer 203 is adopted, rather than a design concept of converting the excitation light 113 into carriers and emitting light again, which is only for the active layer. Therefore, in the high peak value type VCSELs 102 and 300, the thicknesses of the active layers 201 and 301 which are thicker than that of the ordinary photoexcited type VCSEL are important.

Note that, in the present embodiment, in addition to the arrangement of the quantum well layers described above, the plurality of quantum well layers may be arranged in the active layer 301 in an arrangement in which the carriers can be used more effectively than in the first embodiment. That is, in the present embodiment, the plurality of quantum well layers may be arranged so that the center of gravity of the plurality of quantum well layers is biased on the side of the end on which the excitation light 113 enters. Specifically, the plurality of quantum well layers may be arranged so that the center of gravity of the plurality of quantum well layers is located on the side of the end of the active layer 301 on which the excitation light 113 enters from the center in the thickness direction of the active layer 301. In the present embodiment, the case where the quantum well layer is five layers has been described, but the plurality of quantum well layers other than five layers can also be arranged according to the same design concept as described above.

### Third Embodiment

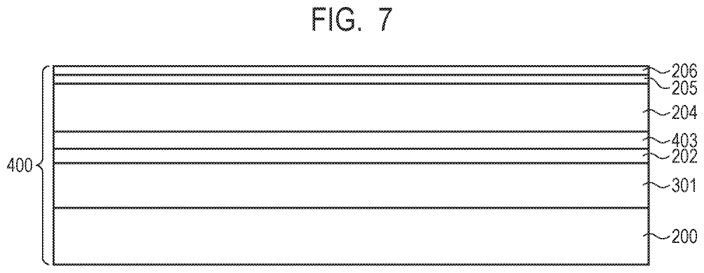

A light emitting device according to a third embodiment of the disclosure will be described with reference to FIG. 7. Components similar to those of the light emitting devices according to the first and second embodiments are denoted by the same reference numerals, and description thereof will be omitted or simplified.

The light emitting device according to the present embodiment is similar to the light emitting device according to the first embodiment except that the configuration of the high peak value type VCSEL is different from that of the light emitting device according to the first embodiment, and has an excitation VCSEL similar to that of the first embodiment. In the present embodiment, parts different from the light emitting device according to the first embodiment will be described mainly, and parts common to the light emitting device according to the first embodiment will be omitted appropriately.

FIG. 7 is a schematic cross-sectional view illustrating a high peak value type VCSEL 400 in the light emitting device according to the present embodiment. The light emitting device according to the present embodiment includes the high peak value type VCSEL 400 instead of the high peak value type VCSEL 102 in the configuration according to the first embodiment. The configuration of the light emitting device according to the present embodiment other than the high peak value type VCSEL 400 is the same as that according to the first embodiment.

The high peak value type VCSEL 400 has a configuration substantially similar to that of the high peak value type VCSEL 300 according to the second embodiment. The high peak value type VCSEL 400 is different from the high peak value type VCSEL 300 in that the high peak value type VCSEL 400 includes a saturable absorption layer 403 that has different material configurations instead of the saturable absorption layer 203. Note that the configuration of the high peak value type VCSEL 400 other than the saturable absorption layer 403 is the same as that of the high peak value type VCSEL 300.

Like the first and second embodiments, the saturable absorption layer 403 may be configured to have a quantum well structure in which four quantum well layers of InGaAs of 8 nm thickness are arranged between barrier layers so as to have a plurality of quantum well layers sandwiched by the barrier layers. On the other hand, in the present embodiment, unlike the first and second embodiments, the barrier layer may be formed of InP rather than InGaAsP. The purpose of making the barrier layer formed of InP rather than InGaAsP is to increase the band gap of the barrier layer in the saturable absorption layer 403 to be greater than the energy of the excitation light 113. Thus, the absorption amount of the excitation light 113 by the barrier layer in the saturable absorption layer 403 is increased, and as a result, the absorption of the excitation light 113 by the entire saturable absorption layer 403 can be decreased.

Specifically, in the high peak value type VCSEL 400 in which the barrier layer of the saturable absorption layer 403 is formed of InP, the absorption rate of the excitation light 113 by the barrier layer of the saturable absorption layer 403 is 10 times higher than in the first and second embodiments in which the barrier layer of the saturable absorption layer 203 is formed of InGaAsP. Therefore, in the present embodiment, as a result, the absorption of the excitation light 113 by the saturable absorption layer 403 can be suppressed to 1/10 or less of the first and second embodiments.

In the present embodiment, in the saturable absorption layer 403, the quantum well layer may be formed of InGaAs. Therefore, in the case of crystal growth of the saturable absorption layer 403, when the barrier layer formed of InP and the quantum well layer formed of InGaAs are grown, switching of the raw material of the group III element and the raw material of the group V element is performed. Especially for the group V element, since the group V element tends to escape from the epitaxial surface at high temperature during epitaxial growth, the degree of difficulty in crystal growth increases. Therefore, from the viewpoint of facilitating crystal growth, the barrier layer of the saturable absorption layer 403 may be formed of InGaAsP in which a small amount of GaAs is added to InP.

Thus, in the present embodiment, the barrier layer of the saturable absorption layer 403 is configured so that the band gap of the barrier layer of the saturable absorption layer 403 is larger than the energy of the excitation light 113. If the material satisfies such band gap, the material constituting the barrier layer is not limited to InP, and materials other than InP may be used as the material constituting the barrier layer.

Note that, in the present embodiment, the case where the saturable absorption layer 403 is formed in place of the saturable absorption layer 203 in the high peak value type VCSEL 300 according to the second embodiment has been described, but the disclosure is not limited thereto. In the high peak value type VCSEL 102 according to the first embodiment, the saturable absorption layer 403 similar to the present embodiment may be formed in place of the saturable absorption layer 203.

### Fourth Embodiment

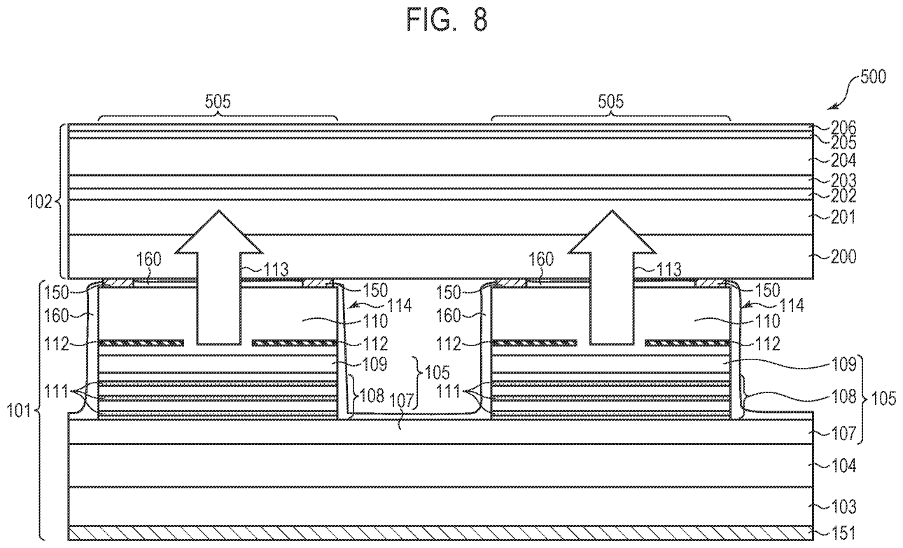

A light emitting device according to a fourth embodiment of the disclosure will be described with reference to FIG. 8. Components similar to those of the light emitting devices according to the first to third embodiments are denoted by the same reference numerals, and description thereof will be omitted or simplified.

Each of the light emitting devices according to the first to third embodiments may be configured as a so-called VCSEL array having a plurality of light emitting portions in the high peak value type VCSEL 102 by providing a plurality of mesa portions in the excitation VCSEL 101. In the present embodiment, a case where the light emitting device according to the first embodiment is configured as a VCSEL array is described.

FIG. 8 is a schematic cross-sectional view illustrating the light emitting device 500 according to the present embodiment. In the light emitting device 500 according to the present embodiment, a plurality of mesa portions 114 are formed in the excitation VCSEL 101. The plurality of mesa portions 114 may be arranged in a two-dimensional array, may be arranged in a linear or curved shape, or may be arranged along a predetermined two-dimensional shape in the excitation VCSEL 101.

The electrode 150 formed in each of the plurality of mesa portions 114 is electrically connected to a common electrode (not illustrated). Current to drive the excitation VCSEL 101 is injected into the excitation VCSEL 101 from an external circuit, which is a driving unit, via the common electrode connected to the plurality of electrodes 150 and the electrode 151.

In the high peak value type VCSEL 102, each portion corresponding to the plurality of mesa portions 114 formed in the excitation VCSEL 101 is a light emitting portion 505. Thus, each of the plurality of light emitting portions 505 present in the high peak value type VCSEL 102 corresponding to the plurality of mesa portions 114 is excited by the excitation light 113 from the mesa portion 114 in the same manner as in the first embodiment, and can emit a light pulse having a high peak value and a short pulse.

Note that, although the case where the VCSEL array is configured using the light emitting device according to the first embodiment has been described above, the VCSEL array using the light emitting device according to the second and third embodiments can be configured in the same manner as described above.

Thus, according to the present embodiment, the VCSEL array using the light emitting device according to the first to third embodiments can be realized. Note that, in the present embodiment, the electrodes 150 are electrically connected to the common electrode, but the disclosure is not limited thereto, and the respective light emitting portions 505 can be independently driven by connecting the electrodes 150 to separate electrodes.

### Fifth Embodiment

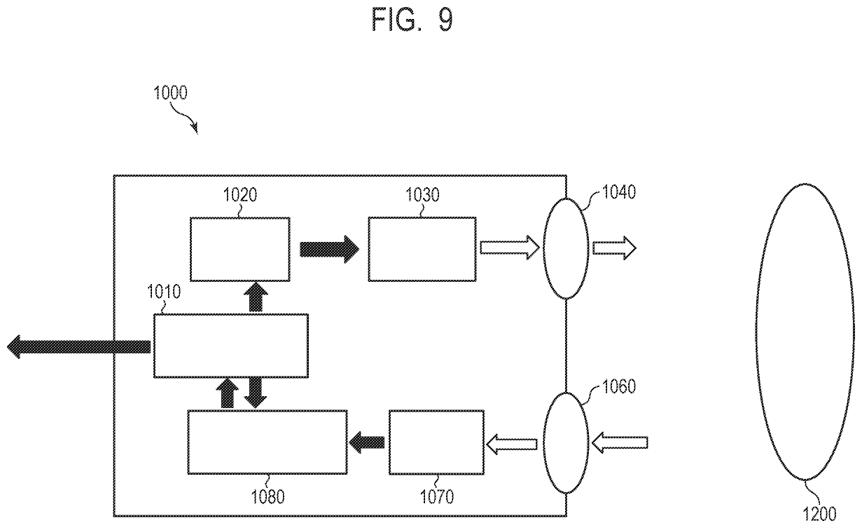

A ranging device according to a fifth embodiment of the disclosure will be described with reference to FIG. 9. FIG. 9 is a block diagram illustrating a schematic configuration of the ranging device according to the present embodiment.

The ranging device 1000 according to the present embodiment is a ranging device (LiDAR apparatus) in which the light emitting device 500 according to the fourth embodiment is applied to a light source unit. The ranging device 1000 may be configured to include a control unit 1010, a surface emitting laser array driver 1020, a surface emitting laser array 1030, a light-emitting side optical system 1040, a light-receiving side optical system 1060, an image sensor 1070, and a distance data processing unit 1080.

The surface emitting laser array 1030 is obtained by mounting the light emitting device 500 according to the fourth embodiment on a package. The surface emitting laser array driver 1020 is a driving unit that receives a drive signal from the control unit 1010, generates a drive current for oscillating the surface emitting laser array 1030, and outputs the driving current to the surface emitting laser array 1030. The drive current output to the surface emitting laser array 1030 is injected into the excitation VCSEL 101 of the light emitting device 500 via the plurality of electrodes 150 and the electrode 151. Note that the surface emitting laser array 1030 and the surface emitting laser array driver 1020 may be one light emitting device.

The light-emitting side optical system 1040 is an optical system that emits the laser light generated by the surface emitting laser array 1030 toward the range to be measured. The light-receiving side optical system 1060 is an optical system that guides the laser light reflected by the object to be measured 1200 to the image sensor 1070. Although the light-emitting side optical system 1040 and the light-receiving side optical system 1060 are represented by a single convex lens-shaped member in FIG. 9, they are not formed of a single convex lens-shaped member, but are formed of a lens group in which a plurality of lenses are combined.

The image sensor 1070 is a photoelectric conversion device in which a plurality of pixels each including a photoelectric conversion portion are arranged in a two-dimensional array, and is a light receiving device that outputs an electric signal corresponding to incident light. The image sensor 1070 may be, for example, an image sensor in which the optical sensors are arranged in a two-dimensional array. The photosensor may be, for example, a Single Photon Avalanche Diode (SPAD) that uses SiGe or InGaAs capable of detecting a SWIR band. A CMOS circuit is electrically connected to this image sensor unit, for example, as a reading unit. The distance data processing unit 1080 has a function as a distance information acquisition unit that generates information on a distance to the object to be measured 1200 existing in the range to be measured based on a signal from the image sensor 1070 and outputs the information. The distance data processing unit 1080 may be electrically connected to the image sensor 1070, and may be disposed in the same package as the image sensor 1070 or may be disposed in a separate package from the image sensor 1070.

The control unit 1010 is formed of an information processing device including a microcomputer, a logic circuit, and the like, and functions as a central processing device that controls the operations of the ranging device 1000 such as operation control of each unit and various calculation processes.

As described above, as a light emitting device suitable for a LiDAR system, a light emitting device capable of generating a light pulse having a short light pulse width and a high peak value may be desirable. Specifically, the light pulse width of the light source suitable for a LiDAR system is, for example, in the range of about 50 ps to 1 ns. On the other hand, from a viewpoint of the VCSEL and an electrical viewpoint for driving the VCSEL, it is not easy to emit light with such a short pulse width. Since the VCSEL emits light in accordance with the amount of injected current, in one embodiment, the current pulse for driving the VCSEL is to be equalized in order to set the light pulse to about 50 ps to 1 ns. That is, from the driver unit to the VCSEL, an electric characteristic is to have excellent in a high frequency band such as 1 GHz or 10 GHz as a frequency component and to handle a current exceeding 1 A. In this case, there is an issue in that the cost is increased as compared with a case where an electric transmission unit up to the driver or the VCSEL is configured only by an electric circuit which handles only a frequency band not more than the above-described frequency band.

Therefore, in the present embodiment, the light emitting device according to the fourth embodiment, in which the VCSEL array is configured by using the light emitting devices according to the first to third embodiments, is used as the light source unit so that the VCSEL itself generates a short pulse. In this way, a light pulse of about 50 ps to 1 ns, which is for the LiDAR system, is realized while avoiding an increase in cost of the driver unit and the electric transmission unit.

Next, the operation of the ranging device 1000 according to the present embodiment will be described with reference to FIG. 9.

First, the control unit 1010 outputs a drive signal to the surface emitting laser array driver 1020. The surface emitting laser array driver 1020 receives the drive signal from the control unit 1010 and injects a current of a predetermined current value into the surface emitting laser array 1030. Thus, the surface emitting laser array 1030 oscillates, and the laser light is output from the surface emitting laser array 1030. At this time, the pulse width of the light emitted from the surface emitting laser array 1030 is narrower than the pulse width of the injected current as described above.

The laser light generated by the surface emitting laser array 1030 is emitted toward the range to be measured by the light-emitting side optical system 1040. Among the laser light irradiated to the object to be measured 1200 in the range to be measured, the laser light reflected by the object to be measured 1200 and incident on the light-receiving side optical system 1060 is guided to the image sensor 1070 by the light-receiving side optical system 1060.

Each pixel of the image sensor 1070 generates an electric signal pulse corresponding to the timing at which the laser light is incident. The electric signal pulse generated by the image sensor 1070 is input to the distance data processing unit 1080.

The distance data processing unit 1080 generates information based on the distance to the object to be measured 1200 along the light propagation direction based on the reception timing of the electric signal pulse output from the image sensor 1070. By calculating distance information based on electric signal pulse output from each pixel of the image sensor 1070, three-dimensional information of the object to be measured 1200 can be acquired.

The ranging device 1000 according to the present embodiment may be applied t, for example, in the field of automobiles, a control device for performing control so as not to collide with other vehicles, a control device for performing control so as to follow the other vehicles and perform automatic driving, and the like. Further, the ranging device 1000 according to the present embodiment may be applied not only to an automobile but also to other movable objects (moving devices) such as a ship, an aircraft, and an industrial robot, a movable object detection system, and the like. The ranging device 1000 according to the present embodiment may be widely applied to equipment that utilizes information of an object recognized three-dimensionally, including distance information. These movable objects may be configured to include the ranging device according to the present embodiment and a control unit that controls the movable object based on information about the distance acquired by the ranging device.

The three-dimensional information including the depth that can be acquired by the ranging device 1000 according to the present embodiment may also be used in an imaging device, an image processing device, a display device, and the like. For example, it is possible to display a virtual object on an image in the real world without discomfort by using three-dimensional information acquired by the ranging device 1000 according to the present embodiment. Further, by storing three-dimensional information together with image information, it is possible to correct a blurred taste or the like of a photographed image after photographing.

As described above, according to the present embodiment, it is possible to realize a high performance ranging device including a light emitting device capable of generating a light pulse having a short light pulse width and a high peak value.

### Sixth Embodiment

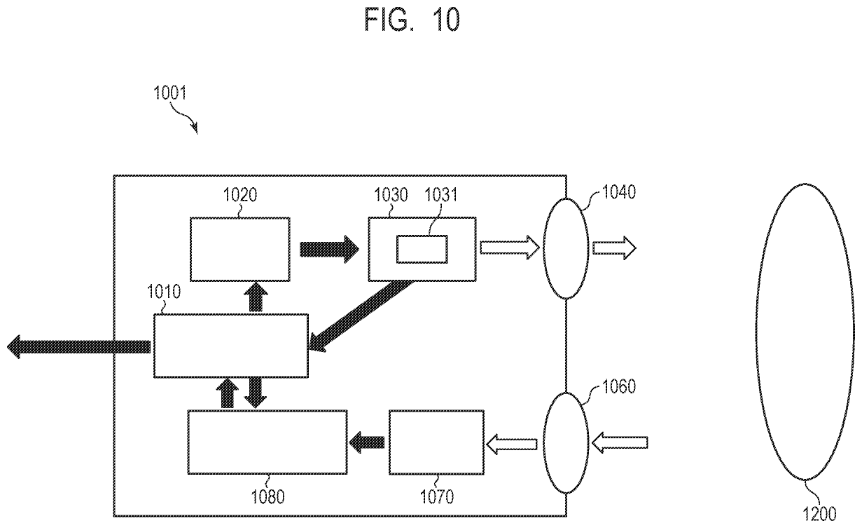

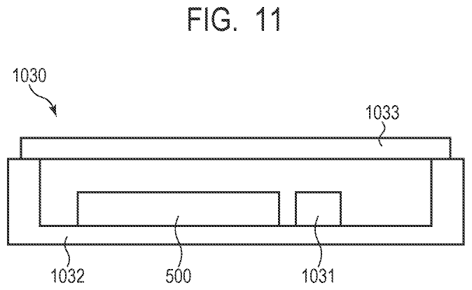

A ranging device according to the sixth embodiment of the disclosure will be described with reference to FIG. 10 and FIG. 11. FIG. 10 is a block diagram illustrating a schematic configuration of the ranging device according to the present embodiment. FIG. 11 is a schematic cross-sectional view illustrating a configuration example of a surface emitting laser array in a ranging device according to the present embodiment. Components similar to those of the light emitting element according to the first to fourth embodiments and the ranging device according to the fifth embodiment are denoted by the same reference numerals, and description thereof will be omitted or simplified.

The ranging device 1001 according to the present embodiment differs from the ranging device 1000 according to the fifth embodiment in that the surface emitting laser array 1030 further includes a light emitting timing monitoring unit 1031 as illustrated in FIG. 10. Other points of the ranging device 1001 according to the present embodiment are the same as those of the ranging device 1000 according to the fifth embodiment.

The surface emitting laser array 1030 includes, for example, as illustrated in FIG. 11, a light emitting device 500, a light emitting timing monitoring unit 1031, a base 1032, and a window member 1033. The base 1032 is a part of a package on which the light emitting device 500 and the light emitting timing monitoring unit 1031 are mounted, and has a concave portion for accommodating the light emitting device 500 and the light emitting timing monitoring unit 1031. The base 1032 may be made of, for example, ceramic. The window member 1033 is fixed to the base 1032 so as to close the concave portion of the base 1032 on which the light emitting device 500 and the light emitting timing monitoring unit 1031 are mounted. The light emitting device 500 is the light emitting device 500 according to the fourth embodiment. The light emitting timing monitoring unit 1031 is formed of a semiconductor substrate having a square shape of, for example, 0.3 mm square, and includes a photodiode having a diameter of the light receiving area of, for example, 100 μm as a light receiving element.

The common electrode to which the electrode 150 of the light emitting device 500 is connected and the electrode 15, and an anode and a cathode of the photodiode constituting the light emitting timing monitoring unit 1031 are electrically connected to electrodes (not illustrated) formed on the outer peripheral portion of the base 1032. The pulse current supplied from the surface emitting laser array driver 1020 is supplied to the light emitting device 500 via the electrodes formed on the base 1032. The electric signal generated by the light emitting timing monitoring unit 1031 is supplied to the distance data processing unit 1080 via electrodes formed on the base 1032.

Next, the operation of the ranging device 1001 according to the present embodiment will be described with reference to FIG. 10 and FIG. 11.

First, the control unit 1010 outputs a drive signal to the surface emitting laser array driver 1020. The surface emitting laser array driver 1020 receives the drive signal from the control unit 1010, and injects a current of a predetermined current value into the light emitting device 500 of the surface emitting laser array 1030. Thereby, the light emitting device 500 oscillates, and a laser light is output from the light emitting device 500. At this time, the pulse width of the light emitted from the light emitting device 500 is narrower than the pulse width of the injected current, as described above.

The laser light generated by the light emitting device 500 is emitted from the surface emitting laser array 1030 through the window member 1033, and is emitted toward the range to be measured by the light-emitting side optical system 1040. At this time, although AR coating is applied to the window member 1033, a part of the light is reflected by the window member 1033 and is incident on the light emission timing monitoring unit 1031.

The light emission timing monitoring unit 1031 receives the incident light and converts the incident light into an electric signal by the photodiode, and outputs the electric signal to the distance data processing unit 1080. The distance data processing unit 1080 generates information on the distance to the object to be measured 1200 along the light propagation direction based on the time difference between the reception timing of the electric signal pulse from the image sensor 1070 and the reception timing of the electric signal from the light emission timing monitoring unit 1031.

The three-dimensional information of the object to be measured 1200 is acquired by calculating distance information based on the electric signal pulse output from each pixel of the image sensor 1070.

Thus, in the ranging device 1001 according to the present embodiment, the light emission timing in the surface emitting laser array 1030 is detected by the light emission timing monitoring unit 1031. The distance information is calculated using the light emission timing detected by the light emission timing monitoring unit 1031. Therefore, even if the light emission timing in the surface emitting laser array 1030 deviates due to factors such as the environmental temperature, it is possible to maintain high distance measurement accuracy without affecting the distance measurement accuracy of the ranging device 1001.

As described above, according to the present embodiment, in the ranging device using the light pulse having a high peak value and a short pulse, it is possible to reduce the influence on the distance measuring accuracy due to a change in the environmental temperature or the like.

### Seventh Embodiment

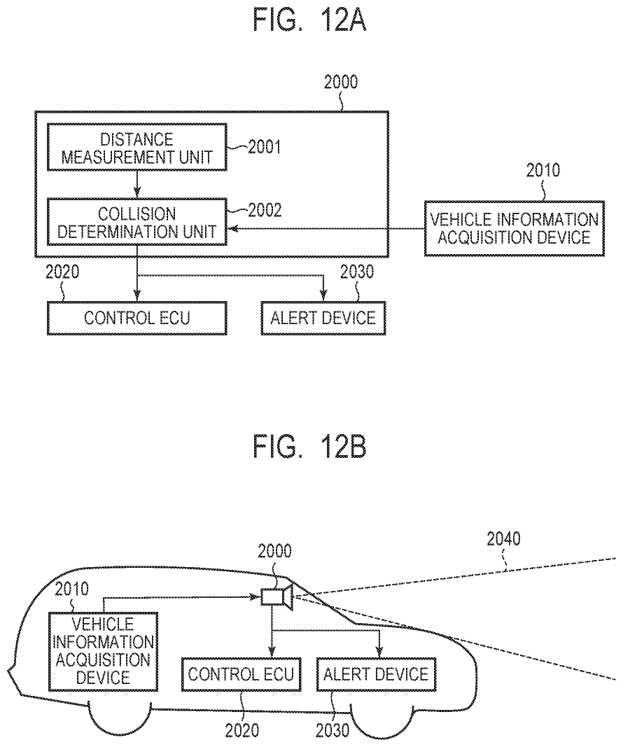

A movable object according to a seventh embodiment of the disclosure will be described with reference to FIG. 12A and FIG. 12B. FIG. 12A and FIG. 12B are diagrams illustrating a configuration example of a movable object according to the present embodiment.

FIG. 12A illustrates a configuration example of equipment 2000 mounted on a vehicle. The equipment 2000 includes a distance measurement unit 2001 and a collision determination unit 2002. The distance measurement unit 2001 is configured by the ranging device 1000 according to the fifth embodiment or the ranging device 1001 according to the sixth embodiment, and measures a distance to an object to acquire information on the distance to the object. The collision determination unit 2002 determines whether or not there is a possibility of collision based on the distance measured by the distance measurement unit 2001.

The equipment 2000 is connected to the vehicle information acquisition device 2010 and can acquire vehicle information such as a vehicle speed, a yaw rate and a steering angle. Further, the equipment 2000 is connected to a control ECU 2020, which is a control device for outputting a control signal for generating a braking force to the vehicle based on the determination result of the collision determination unit 2002. The equipment 2000 is also connected to an alert device 2030 that issues an alert to the driver based on the determination result of the collision determination unit 2002. For example, when the collision possibility is high as the determination result of the collision determination unit 2002, the control ECU 2020 instructs the vehicle to perform a brake operation, an accelerator stop, an engine output suppression, and the like, thereby avoiding the collision and reducing damage. The alert device 2030 alerts the user by sounding an alert such as a sound, displaying alert information on a screen of a car navigation system or the like, or giving vibration to a seat belt or a steering wheel. These devices of the equipment 2000 function as a movable object control unit that controls the operation of controlling the vehicle as described above.

In the present embodiment, the equipment 2000 measures the distance around the vehicle, for example, the front or the rear. FIG. 12B illustrates the equipment 2000 when distance measurement is performed in front of the vehicle (distance measurement area 2040). The vehicle information acquisition device 2010 as the distance measuring control means sends an instruction to the equipment 2000 or the distance measurement unit 2001 to perform the distance measurement operation. With such a configuration, the accuracy of distance measurement can be further improved.

Although the control of collision avoidance with other vehicles has been described above, the present embodiment is also applicable to control of automatic driving following other vehicles, control of automatic driving so as not to go beyond a lane, and the like. Further, the equipment is not limited to a vehicle such as an automobile, and can be applied to a movable object (moving device) such as a ship, an aircraft, an artificial satellite, an industrial robot, or a consumer robot. In addition, the disclosure can be applied not only to a movable object but also to a wide variety of equipment using object recognition or biological recognition, such as an intelligent transport system (ITS) and a surveillance system.

### Modified Embodiments

The disclosure is not limited to the above-described embodiments, and various modifications are possible.

For example, an example in which some of the configurations of any of the embodiments are added to other embodiments or an example in which some of the configurations of any of the embodiments are substituted with some of the configurations of the other embodiments is also an embodiment of the disclosure.

In the above-described embodiments, the mesa type VCSEL having an oscillation wavelength of 940 nm is used as the excitation VCSEL 101, and the VCSEL having an oscillation wavelength of 1550 nm is used as the high peak value type VCSEL 102, but the disclosure is not limited thereto. The disclosure can be applied to other configuration examples with the same idea.

For example, in one embodiment, the VCSEL is an excitation light source that emits the excitation light toward the high peak value type VCSEL 102, but the excitation light source may be any light source that can emit the excitation light toward the high peak value type VCSEL 102.

Specifically, instead of the excitation VCSEL 101, another type of excitation light source such as a photonic crystal laser or an end surface emitting laser, or the like may be used. A semiconductor light emitting element as the excitation light source may include an active layer that generates light by injecting a current and a resonator portion that oscillates the light generated in the active layer. For example, in the photonic crystal laser, the photonic crystal itself functions as a reflector, and in the end surface light emitting laser, the cleaved surface functions as a reflector. In addition, a semiconductor light emitting element such as the excitation VCSEL 101 used as the excitation light source does not necessarily have a mesa-type structure, and may has a structure in which a region where a current is injected is specified by patterning a transparent electrode such as the electrode 150 or the like, for example. Further, the wavelength of the excitation light emitted from the excitation light source such as the excitation VCSEL 101 is not limited to the above wavelength, and may be shorter than the oscillation wavelength of the high peak value type VCSEL 102. The oscillation wavelength of the high peak value type VCSEL 102 is not limited to the above wavelength, and may be longer than the wavelength of the excitation light.

In the above-described embodiments, the GaAs-based material system for the excitation VCSEL 101 and the InP-based material system for the high-peak VCSEL 102 are exemplified, but the material systems are not limited to these. For each of the material systems of excitation VCSEL 101 and the high peak value VCSEL 102, another material system such as a GaN-based material system or the like, for example, can be used as appropriate.

Further, the DBR layers in the excitation VCSEL 101 and the high peak value type VCSEL 102 according to the above-described embodiments are not necessarily formed of the above-described materials, but may be formed of other materials. In this case as well, the same effect as that of the present embodiment can be obtained by configuring so as to achieve the same functions as those of the above-described embodiments.

It should be noted that any of the above-described embodiments is merely an example of an embodiment for carrying out the disclosure, and the technical scope of the disclosure should not be construed as being limited thereto. That is, the disclosure can be implemented in various forms without departing from the technical idea or the main features thereof.

The disclosures of the present embodiments include the following configurations.

### (Configuration 1)

A light emitting device comprising:
a first semiconductor light emitting element that includes a first active layer and a first resonator portion over a semiconductor substrate, and emits a first light;
a second semiconductor light emitting element that includes a first reflector, a second resonator portion including a second active layer excited by the first light, and a second reflector stacked in this order over the first semiconductor light emitting element, and emits a second light; and
a driving unit that injects a current into the first semiconductor light emitting element,
wherein an oscillation wavelength of the second semiconductor light emitting element is longer than an oscillation wavelength of the first semiconductor light emitting element,
wherein the second semiconductor light emitting element includes a saturable absorption layer between the second resonator portion and the second reflector, and
wherein a thickness L of the second active layer and an absorption coefficient α of the second active layer satisfy the following expression (1).

$$\\ \begin{matrix}3.45 \leq α \times L \leq 15 & ( 1 )\end{matrix}$$

### (Configuration 2)

The light emitting device according to Configuration 1, wherein the first semiconductor light emitting element includes a third reflector, a first resonator portion including the first active layer, and a fourth reflector stacked in this order over the semiconductor substrate.

### (Configuration 3)

The light emitting device according to Configuration 1 or 2, comprising a carrier blocking layer formed between the second resonator portion and the saturable absorption layer.

### (Configuration 4)

The light emitting device according to any one of Configurations 1 to 3, wherein the second active layer has a thickness such that an amount of absorption of the first light is 90% or more.

### (Configuration 5)

The light emitting device according to any one of Configurations 1 to 4, wherein the thickness L of the second active layer and the absorption coefficient α of the second active layer satisfy the following expression 2).

$$\\ \begin{matrix}4.2 \leq α \times L \leq 7.5 & ( 2 )\end{matrix}$$

### (Configuration 6)

The light emitting device according to any one of Configurations 1 to 4, wherein the thickness L satisfies the following expression (3).

$$\\ \begin{matrix}2.3 µm \leq L \leq 10 µm & ( 3 )\end{matrix}$$

### (Configuration 7)

The light emitting device according to any one of Configurations 1 to 4, wherein the thickness L satisfies the following expression (4).

$$\\ \begin{matrix}2.8 µm \leq L \leq 5 µm & ( 4 )\end{matrix}$$

### (Configuration 8)

The light emitting device according to any one of Configurations 1 to 6, wherein the second semiconductor light emitting element is configured to emit the second light having a profile that has a maximum peak value and converges to a stable value that is a predetermined light intensity after the maximum peak value.

### (Configuration 9)

The light emitting device according to any one of Configurations 1 to 8, wherein the second active layer includes a plurality of quantum well layers.

### (Configuration 10)

The light emitting device according to Configuration 9, wherein the plurality of quantum well layers are located at antinode positions of a standing wave generated in the second active layer.

### (Configuration 11)

The light emitting device according to Configuration 9 or 10, wherein a center of gravity of the plurality of quantum well layers is located at a center in a thickness direction of the second active layer.

### (Configuration 12)

The light emitting device according to Configuration 9 or 10, wherein a center of gravity of the plurality of quantum well layers is located on a side of an end of the second active layer from which the first light enters the second active layer rather than a center in a thickness direction of the second active layer.

### (Configuration 13)

The light emitting device according to any one of Configurations 1 to 12, wherein the saturable absorption layer includes quantum well layers and barrier layers formed above and below each quantum well layer, and

wherein a band gap of the barrier layer is greater than or equal to an energy of the first light.

### (Configuration 14)

The light emitting device according to Configuration 13, wherein the barrier layer is formed of InP or InGaAsP.

### (Configuration 15)

The light emitting device according to any one of Configurations 1 to 14, wherein the second active layer includes a quantum well layer and barrier layers formed above and below the quantum well layer,

wherein the barrier layer is formed of InGaAsP, and

wherein the quantum well layer is formed of InGaAs.

### (Configuration 16)

The light emitting device according to any one of Configurations 1 to 15, wherein the first semiconductor light emitting element includes a plurality of first light emitting portions that emit the first light.

### (Configuration 17)

The light emitting device according to Configuration 16, wherein the first light emitting portion includes the first active layer shaped in a mesa.

### (Configuration 18)

The light emitting device according to Configuration 16 or 17, wherein the plurality of the first light emitting portions are arranged in a two-dimensional array.

### (Configuration 19)

The light emitting device according to any one of Configurations 16 to 18, wherein the second semiconductor light emitting element includes a plurality of second light emitting portions that emit the second light corresponding to the plurality of first light emitting portions.

### (Configuration 20)

The light emitting device according to any one of Configurations 1 to 19, further comprising a light receiving element that receives the second light emitted from the second semiconductor light emitting element.

### (Configuration 21)

A ranging device comprising:

the light emitting device according to any one of Configurations 1 to 20;

a light receiving device configured to receive light emitted from the light emitting device and reflected by an object to be measured; and
a distance information acquisition unit configured to acquire information on a distance to the object to be measured based on a time difference between a timing at which light is emitted from the light emitting device and a timing at which light is received by the light receiving device.

### (Configuration 22)

A movable object comprising:

the ranging device according to Configuration 21; and

a control unit configured to control the movable object based on information on the distance acquired by the ranging device.

According to the aspect of the embodiments, it is possible to realize a light emitting device that can generate a light pulse having a short optical pulse width and a high peak value in a long wavelength region, as well as a ranging device and a movable object using such a light emitting device.

While the disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-051249, filed Mar. 28, 2023, which is hereby incorporated by reference herein in its entirety.

What is claimed is:

1. A light emitting device comprising:
a first semiconductor light emitting element that includes a first active layer and a first resonator portion over a semiconductor substrate, and emits a first light;
a second semiconductor light emitting element that includes a first reflector, a second resonator portion including a second active layer excited by the first light, and a second reflector stacked in this order over the first semiconductor light emitting element, and emits a second light; and
a driving unit that injects a current into the first semiconductor light emitting element,
wherein an oscillation wavelength of the second semiconductor light emitting element is longer than an oscillation wavelength of the first semiconductor light emitting element,
wherein the second semiconductor light emitting element includes a saturable absorption layer between the second resonator portion and the second reflector, and
wherein a thickness L of the second active layer and an absorption coefficient α of the second active layer satisfy the following inequality.
$$\\ 3.45 \leq α \times L \leq 15$$

2. The light emitting device according to claim 1, wherein the first semiconductor light emitting element includes a third reflector, a first resonator portion including the first active layer, and a fourth reflector stacked in this order over the semiconductor substrate.

3. The light emitting device according to claim 1, further comprising a carrier blocking layer formed between the second resonator portion and the saturable absorption layer.

4. The light emitting device according to claim 1, wherein the second active layer has a thickness such that an amount of absorption of the first light is 90% or more.

5. The light emitting device according to claim 1, wherein the thickness L of the second active layer and the absorption coefficient α of the second active layer satisfy the following inequality.
$$\\ 4.2 \leq α \times L \leq 7.5$$

6. The light emitting device according to claim 1, wherein the thickness L satisfies the following inequality.
$$\\ 2.3 µm \leq L \leq 10 µm$$

7. The light emitting device according to claim 1, wherein the thickness L satisfies the following inequality.
$$\\ 2.8 µm \leq L \leq 5 µm$$

8. The light emitting device according to claim 1, wherein the second semiconductor light emitting element is configured to emit the second light having a profile that has a maximum peak value and converges to a stable value that is a predetermined light intensity after the maximum peak value.

9. The light emitting device according to claim 1, wherein the second active layer includes a plurality of quantum well layers.

10. The light emitting device according to claim 9, wherein the plurality of quantum well layers are located at antinode positions of a standing wave generated in the second active layer.

11. The light emitting device according to claim 9, wherein a center of gravity of the plurality of quantum well layers is located at a center in a thickness direction of the second active layer.

12. The light emitting device according to claim 9, wherein a center of gravity of the plurality of quantum well layers is located on a side of an end of the second active layer from which the first light enters the second active layer rather than a center in a thickness direction of the second active layer.

13. The light emitting device according to claim 1, wherein the saturable absorption layer includes quantum well layers and barrier layers formed above and below each quantum well layer, and
wherein a band gap of the barrier layer is greater than or equal to an energy of the first light.

14. The light emitting device according to claim 13, wherein the barrier layer is formed of InP or InGaAsP.

15. The light emitting device according to claim 1, wherein the second active layer includes a quantum well layer and barrier layers formed above and below the quantum well layer,
wherein the barrier layer is formed of InGaAsP, and
wherein the quantum well layer is formed of InGaAs.

16. The light emitting device according to claim 1, wherein the first semiconductor light emitting element includes a plurality of first light emitting portions that emit the first light.

17. The light emitting device according to claim 16, wherein a first light emitting portion of the plurality of first portions includes the first active layer shaped in a mesa.

18. The light emitting device according to claim 16, wherein the plurality of the first light emitting portions are arranged in a two-dimensional array.

19. The light emitting device according to claim 16, wherein the second semiconductor light emitting element includes a plurality of second light emitting portions that emit the second light corresponding to the plurality of first light emitting portions.

20. The light emitting device according to claim 1, further comprising a light receiving element that receives the second light emitted from the second semiconductor light emitting element.

21. A ranging device comprising:
the light emitting device according to claim 1;
a light receiving device configured to receive light emitted from the light emitting device and reflected by an object to be measured; and
an acquisition unit configured to acquire information on a distance to the object to be measured based on a time difference between a timing at which light is emitted from the light emitting device and a timing at which light is received by the light receiving device.

22. A movable object comprising:
the ranging device according to claim 21; and
a control unit configured to control the movable object based on information on the acquired distance.
